(19) United States
(12) Patent Application Publication
(10) Pub. No.: US 2026/0114120 A1
(43) Pub. Date: Apr. 23, 2026

(54) COMPOSITE MATERIAL, PHOTOELECTRIC DEVICE AND PREPARATION METHOD THEREFOR

(71) Applicant: TCL Technology Group Corporation, Huizhou, Guangdong (CN)

(72) Inventor: Qiang LUO, Huizhou, Guangdong (CN)

(73) Assignee: TCL Technology Group Corporation, Huizhou, Guangdong (CN)

(21) Appl. No.: 19/117,027

(22) PCT Filed: Sep. 18, 2023
(86) PCT No.: PCT/CN2023/119400

§ 371 Date: Mar. 28, 2025

(30) Foreign Application Priority Data
Sep. 29, 2022 (CN) 202211199667.X

(51) Int. Cl. H10K 50/16; H10K 50/115; H10K 71/15; H10K 85/30

(52) U.S. Cl. CPC H10K 50/16; H10K 50/115; H10K 71/15; H10K 85/30

(57) ABSTRACT

The present disclosure discloses a composite material, a photoelectric device and a preparation method therefor. The composite material includes a metal oxide and a glycerol-based metal compound. The coordination of the metal oxide and the glycerol-based metal compound could improve the thermal stability and storage stability of the composite material.

The present disclosure claims priority to Chinese Application NO. 202211199667.X filed in the China National Intellectual Property Administration on Sep. 29, 2022 and entitled “COMPOSITE MATERIAL, PHOTOELECTRIC DEVICE AND PREPARATION METHOD THEREFOR”, the content of which is incorporated herein by reference in its entirety.

### TECHNICAL FIELD

The present disclosure relates to a field of display technologies, and more particularly, to composite material, photoelectric device and preparation method therefor.

### BACKGROUND

In the related art, the storage stability of metal oxides under the conditions of illumination and high temperature (>60° C.) is poor, which leads to limited application scenarios of metal oxides. Through analysis, the main reason for the poor storage stability of metal oxides under illumination and high temperature is the poor thermal stability and light stability of metal oxides.

On the one hand, when the storage temperature is higher than 60° C., metal oxides are prone to aging, leading to performance degradation. On the other hand, metal oxides are prone to photohydration reaction under illumination, which leads to lose effectiveness.

### Technical Solution

In view of this, the present disclosure provides a composite material, a photoelectric device and a preparation method therefor.

The present disclosure provides a composite material. The composite material including: a metal oxide; and a glycerol-based metal compound.

Alternatively, the composite material consists of the metal oxide and the glycerol-based metal compound.

Alternatively, a metal element in the glycerol-based metal compound is selected from one or more of Zn, Sn, In, Fe, Cr, Ti, W, Cd, Cu and Mo.

The metal oxide is selected from one or more of ZnO, SnO₂, ITO, Fe₂O₃, CrO₃, TiO₂, WO₃, CdO, CuO and MoO₂.

Alternatively, the glycerol-based metal compound is zinc glyceryl.

Alternatively, a molar ratio between the glycerol-based metal compound and the metal oxide is (1-9):100.

The metal oxide is metal oxide nanoparticle, and an average particle size of the metal oxide nanoparticle ranges between 3-5 nm.

Alternatively, a surface of the metal oxide and/or a surface of the glycerol-based metal compound is bonded with hydrophobic group.

Alternatively, the hydrophobic group is selected from one or more of vinyl group, nitro group and halogen atom group.

Alternatively, the surface of the metal oxide is bonded with a first hydrophobic group, and the surface of the glycerol-based metal compound is bonded with a second hydrophobic group; and the first hydrophobic group and the second hydrophobic group are independently selected from one or more of vinyl group, nitro group and halogen atom group.

The present disclosure provides a photoelectric device, including: a cathode, an anode; and a functional layer, between the cathode and the anode, wherein the functional layer includes an electron transport layer, and a material of the electron transport layer includes the composite material mentioned above.

Alternatively, a material of the cathode is selected from one or more of metallic materials, carbon materials and metal oxides. The metallic materials are selected from one or more of Al, Ag, Cu, Mo, Au, Ba, Ca and Mg, the carbon materials are selected from one or more of graphite, carbon nanotube, graphene, and carbon fiber, and the metal oxides are selected from one or more of ITO, FTO, ATO, AZO, GZO, IZO, MZO and AMO.

A material of the anode is selected from one or more of ITO, FTO, IZO, ITZO, ICO, SnO₂, In₂O₃, Cd:ZnO, F:SnO₂, In:SnO₂, Ga:SnO₂, AZO, Ni, Pt, Au, Ag and Ir.

Alternatively, the functional layer further includes a light emitting layer which disposed between the electron transport layer and the anode.

Alternatively, a material of the light emitting layer is selected from one or more of single-component and/or core-shell structure II-VI compound, single-component and/or core-shell structure III-V compound, single-component and/or core-shell structure IV-VI compound, single-component and/or core-shell structure I-III-VI compound, inorganic perovskite quantum dot, organic perovskite quantum dots and organic-inorganic hybrid perovskite quantum dot; the II-VI compound is selected from one or more of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe and HgZnSTe; the III-V compound is selected from one or more of GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs and InAlPSb; the IV-VI compound is selected from one or more of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe and SnPbSTe; and the I-III-VI compound is selected from one or more of CuInS₂, CuInSe₂ and AgInS₂.

a general structural formula of the inorganic perovskite quantum dot is AMX₃, where A is Cs⁺, M is divalent metal cation selected from Pb²⁺, Sn²⁺, Cu²⁺, Ni²⁺, Cd²⁺, Cr²⁺, Mn²⁺, Co²⁺, Fe²⁺, Ge²⁺, Yb²⁺ or Eu²⁺, and X is halogen anion selected from Cl⁻, Br⁻ or I⁻.

A general structural formula of the organic perovskite quantum dot is CMX₃, where C is formamidinyl, M is divalent metal cation selected from Pb²⁺, Sn²⁺, Cu²⁺, Ni²⁺, Cd²⁺, Cr²⁺, Mn²⁺, Co²⁺, Fe²⁺, Ge²⁺, Yb²⁺ or Eu²⁺, and X is halogen anion selected from Cl⁻, Br⁻ or I⁻.

A general structural formula of the organic-inorganic hybrid quantum dot is BMX₃, where B is organic amine cations selected from CH₃(CH₂)ₙ₋₂NH³⁺ (n≥2) or NH₃(CH₂)ₙNH₃²⁺ (n≥2), Mis divalent metal cation selected from Pb²⁺, Sn²⁺, Cu²⁺, Ni²⁺, Cd²⁺, Cr²⁺, Mn²⁺, Co²⁺, Fe²⁺, Ge²⁺, Yb²⁺ or Eu²⁺, and X is halogen anion selected from Cl⁻, Br⁻ or I⁻.

Alternatively, the functional layer further includes a hole functional layer which disposed between the light emitting layer and the anode, and the hole functional layer includes one or more of a hole injection layer and a hole transport layer.

Alternatively, a material of the hole injection layer is selected from one or more of poly (3,4-ethylenedioxythiophene)-polystyrene sulfonic acid, 2,3,5,6-tetrafluoro-7,7′,8,8′-tetracyanomethyl-p-benzoquinone, copper phthalocyanine, 1,4,5,8,9,11-hexaazabenzonitrile, NiOₓ, MoOₓ, WOₓ, CrOₓ, CuO, MoSₓ, MoSeₓ, WSₓ, WSeₓ and CuS; and a value range of x is 1-3; and/or, a material of the hole transport layer is selected from one or more of poly (9,9-dioctyl fluorene-CO—N-(4-butylphenyl)diphenylamine), polyvinyl carbazole, poly (N,N′ bis(4-butylphenyl)-N,N′-bis(phenyl)benzidine), 4,4′,4″-tris(carbazole-9-yl)triphenylamine, 4,4′-bis (9-carbazole) biphenyl, N,N′-diphenyl-N,N′-bis(3-methylphenyl)-1,1′-biphenyl-4,4′-diamine and N,N′-diphenyl-N,N′-(1-naphthyl)-1, l′-biphenyl-4,4′-diamine.

The present disclosure provides a preparation method of a photoelectric device, including: providing a first substrate, and the first substrate includes a first electrode; providing a first film-forming solution, the first film-forming solution includes a solvent and a solute, and the solute includes a metal oxide and a glyceryl-based metal compound, and disposing the first film-forming solution on the first substrate to form an electron transport layer; and forming a second electrode on the electron transport layer to obtain a photoelectric device.

Alternatively, the first substrate includes an anode and a light emitting layer which are stacked; disposing the first film-forming solution on the side of the light emitting layer far from the anode to form the electron transport layer; forming a cathode on the electron transport layer to obtain the photoelectric device.

Alternatively, the first substrate includes a cathode; disposing the first film-forming solution on the cathode to form the electron transport layer; forming a light emitting layer and an anode on the electron transport layer to obtain the photoelectric device.

Alternatively, metal element in the glycerol-based metal compound is selected from one or more of Zn, Sn, In, Fe, Cr, Ti, W, Cd, Cu and Mo.

The metal oxide is selected from one or more of ZnO, SnO₂, ITO, Fe₂O₃, CrO₃, TiO₂, WO₃, CdO, CuO and MoO₂.

Alternatively, the glycerol-based metal compound is zinc glyceryl.

Alternatively, a molar ratio between the glycerol-based metal compound and the metal oxide is (1-9):100.

A solvent in the first film-forming solution is selected from one or more of ethanol, propanol, 2propanol, n-butanol, 2butanol, tert-butanol, n-amyl alcohol, n,n-dimethylformamide and dimethyl sulfoxide.

Glycerol metal oxide is introduced into the composite material provided by the present disclosure, so that the thermal stability of the composite material could be effectively improved, and the composite material could still maintain good performance even after being stored at a high temperature above 60° C. or working at a high temperature above 60° C. In addition, glycerol-based metal compound also has the advantages of innocuity, environmental friendliness and low cost, which is conducive to large-scale mass production and application.

### BRIEF DESCRIPTION OF DRAWINGS

In order to more clearly explain the technical solutions in the embodiments of the present disclosure, the following will briefly introduce the drawings required in the description of the embodiments. Obviously, the drawings in the following description are only some embodiments of the present disclosure. For those skilled in the art, without paying any creative work, other drawings can be obtained based on these drawings.

FIG. 1 is a schematic diagram of the structure of a photoelectric device according to an embodiment of the present disclosure.

FIG. 2 is a schematic diagram of the structure of a photoelectric device according to another embodiment of the present disclosure.

FIG. 3 is a flowchart of a method for preparing a photoelectric device according to an embodiment of the present disclosure.

FIG. 4 is a schematic diagram of nitro group bonding on the surface of ZnO in Example 6 of the present disclosure.

In which, the reference numeral indicates:
anode 10; light emitting layer 20; electron transport layer 30; cathode 40; hole functional layer 50.

### DETAILED DESCRIPTION

Technical solutions in embodiments of the present disclosure will be clearly and completely described below in conjunction with drawings in the embodiments of the present disclosure. Obviously, the described embodiments are only a part of embodiments of the present disclosure, rather than all the embodiments. Based on the embodiments in the present disclosure, all other embodiments obtained by those skilled in the art without creative work fall within the protection scope of the present disclosure.

The embodiment of the present disclosure provides a composite material, and a photoelectric device and a preparation method therefor. The following are described in detail. It should be noted that the description order of the following embodiments is not taken as a limitation to the preferred order of the embodiments. In addition, in the description of the present disclosure, the term “comprising/including” means “comprising/including but not limited to”. The terms “first, second, third, etc”. are only used as signs and do not impose numerical requirements or establish order.

In the present disclosure, the term “and/or” is used to describe the association of associated objects, and means that there may be three relationships, for example, “A and/or B” may refer to three cases: the first case refers to the presence of A alone; the second case refers to the presence of both A and B; the third case refers to the presence of B alone, where A and B may be singular or plural.

In the present disclosure, the term “at least one” refers to one or more, and “a plurality of/multiple” refers to two or more. The terms “at least one”, “at least one of the followings”, or the like, refer to any combination of the items listed, including any combination of the singular or the plural items. For example, “at least one of a, b, or c” or “at least one of a, b, and c” may refer to: a, b, c, a-b (i.e., a and b), a-c, b-c, or a-b-c, where a, b, and c may be single or plural.

Additionally, in the description of the present disclosure, various embodiments of the present disclosure may be presented in a form of range. It should be understood that the description in the form of range is merely for convenience and brevity, and should not be construed as a hard limitation on the scope of the disclosure. Accordingly, it should be considered that the recited range description has specifically disclosed all possible subranges, as well as a single numerical value within that range. For example, it should be considered that a description of a range from 1 to 6 has specifically disclosed subranges, such as from 1 to 3, from 1 to 4, from 1 to 5, from 2 to 4, from 2 to 6, from 3 to 6, etc., and a single number within the range, such as 1, 2, 3, 4, 5, and 6, regardless of the range. Whenever a range of values is indicated herein, it is meant to include any recited number (fraction or integer) within the indicated range.

The first aspect, the present disclosure discloses a composite material. The composite material includes a metal oxide and a glycerol-based metal compound.

The coordination of the metal oxide and the glycerol-based metal compound could improve the thermal stability and storage stability of the composite material. When the composite material is applied to the electron transport layer 30 of photoelectric device, the performance of the photoelectric device is more excellent in terms of efficiency and life.

In some embodiments, a metal element in the glycerol-based metal compound could be selected from one or more of Zn, Sn, In, Fe, Cr, Ti, W, Cd, Cu and Mo. In other words, the glycerol-based metal compound could be selected from one or more of zinc glycerol, tin glycerol, indium glycerol, iron glycerol, chromium glycerol, titanium glycerol, tungsten glycerol, cadmium glycerol, copper glycerol and molybdenum glycerol.

In some embodiments, the glycerol-based metal compound is zinc glyceryl.

In some embodiments, the metal oxide could be selected from one or more of ZnO, SnO₂, ITO, Fe₂O₃, CrO₃, TiO₂, WO₃, CdO, CuO and MoO₂.

In some embodiments, the metal oxide is metal oxide nanoparticle, and an average particle size of the metal oxide nanoparticle ranges between 3-5 nm.

In some embodiments, a surface of the metal oxide and/or a surface of the glycerol-based metal compound is bonded with hydrophobic group.

Further, the hydrophobic group is selected from one or more of vinyl group, nitro group and halogen atom group.

In some embodiments, the hydrophobic group could be bonded to the surface of the metal oxides and/or the glycerol-based metal compound in the form of ligands. After the surface of the metal oxide and/or the glycerol-based metal compound is bonded with the hydrophobic group, the photo-hydration reaction of the metal oxide and/or the glycerol-based metal compound under the illumination condition could be prevented, and the light stability of the composite material could be improved.

In some embodiments, it could be only the surface of the metal oxide is bonded with the hydrophobic group, or only the surface of the glycerol-based metal is bonded with the hydrophobic group, or both the surfaces of the metal oxide and the glycerol-based metal compound are bonded with the hydrophobic group.

In some embodiments, the surface of the metal oxide is bonded with the hydrophobic group.

In some embodiments, both the surfaces of the metal oxide and the glycerol-based metal compound are bonded with the hydrophobic group. Specifically, the surface of the metal oxide is bonded with a first hydrophobic group, and the surface of the glycerol-based metal compound is bonded with a second hydrophobic group. The first hydrophobic group and the second hydrophobic group are independently selected from one or more of vinyl group, nitro group and halogen atom group.

In some embodiments, the hydrophobic group is selected from one or more of vinyl group, nitro group and halogen atom group.

In some embodiments, ligand exchange could be carried out on the metal oxide, so that the surface of the metal oxide is bonded with the hydrophobic group.

It should be noted that in order to bond the hydrophobic group on the surface of the metal oxide through ligand exchange, the metal oxide could be first subjected to ligand exchange to bond the hydrophobic group on the surface of the metal oxide, and then mixed with the glycerol-based metal compound. It is also possible to mix the glycerol-based metal compound and the metal oxide before ligand exchange.

Specifically, the ligand exchange includes: the metal oxide, a reagent for ligand exchange and a polar organic solvent is mixed.

Further, the reagent for ligand exchange could be different according to the types of hydrophobic group. For example, in the case that the hydrophobic group is the nitro, the reagent for ligand exchange could be an amino metal compound (such as sodium amino). However, it should be noted that when using amino metal compound for the ligand exchange, the introduced group is amino, and in order to convert amino into nitro, an oxidant could be added. The oxidant could be selected from one or more of hydrogen peroxide and persulfate. In the case that the hydrophobic group is the vinyl, the reagent for ligand exchange could be selected from, but not limited to, vinyl chloride. In the case that the hydrophobic group is the halogen atom, the reagent for ligand exchange could be selected from, but not limited to, alkali metal halide salts.

In some embodiments, a molar ratio between the glycerol-based metal compound and the metal oxide is (1-9):100, such as 2:100, 3:100, 4:100, 5:100, 6:100, 7:100, 8:100, etc.

In some embodiments, the metal oxide and the glycerol-based metal compound could be mixed to obtain the composite material.

In some embodiments, when the metal oxide and the glycerol-based metal compound are mixed, the metal oxide and the glycerol-based metal compound could be directly provided and mixed. Further, the mixing of the metal oxide and the glycerol-based metal compound could be carried out in a polar organic solvent. The polar organic solvent could be selected from but not limited to one or more of methanol, ethanol, butanol and isopropanol.

In some embodiments, mixing the metal oxide, the reagent for ligand exchange and the polar organic solvent could include: a cationic solution is obtained by mixing the metal oxide with the polar organic solvent; a ligand exchange solution is obtained by mixing the cationic solution with the reagent for ligand exchange; the ligand exchange solution and glycerol is mixed.

In other embodiments, mixing the metal oxide, the reagent for ligand exchange and the polar organic solvent could include: the metal oxide, glycerol and the polar organic solvent are mixed at the same time to obtain a mixed solution, and then the mixed solution is mixed with the reagent for ligand exchange.

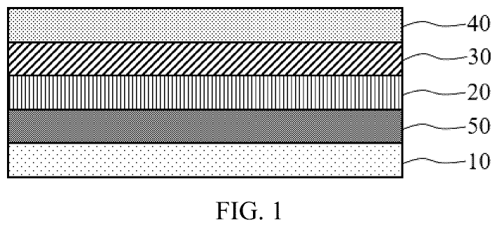

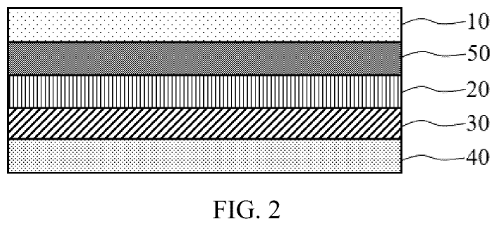

In the second aspect, referring to FIG. 1 and FIG. 2, the present disclosure also discloses a photoelectric device. The photoelectric device including:
a cathode 40,
an anode 10; and
a functional layer, between the cathode 40 and the anode 10, wherein the functional layer includes an electron transport layer 30, and a material of the electron transport layer 30 includes the composite material, or a material of the electron transport layer 30 includes the composite material prepared by the preparation method.

In some embodiments, the photoelectric device could be one of a light emitting diode, a solar cell and a photodetector.

In some embodiments, the photoelectric device could be a light emitting diode. The light emitting diode could be one of organic light emitting diode, quantum dot light emitting diode and micron light emitting diode. In some embodiments, the light emitting diode could be a quantum dot light emitting diode. Further, the light emitting diode could be a light emitting diode with an upright structure or an inverted structure. The light emitting diode could be a top emitting device, a bottom emitting device or a double-sided emitting device, which is not limited.

In some embodiments, the functional layer could further include a light emitting layer 20, disposed between the electron transport layer 30 and the anode 10.

In some embodiments, the functional layer could further include a hole functional layer 50, disposed between the light emitting layer 20 and the anode 10.

The hole functional layer 50 includes one or more of a hole injection layer and a hole transport layer.

Further, the photoelectric device could include the anode 10, the hole injection layer, the hole transport layer, the light emitting layer 20, the electron transport layer 30, and the cathode 40 which are sequentially stacked. The photoelectric device could also include other functional layers such as electron injection layer, hole blocking layer and electron blocking layer, which are not limited.

In some embodiments, a material of the anode 10 could be selected from one or more of ITO, FTO, IZO, ITZO, ICO, SnO₂, In₂O₃, Cd:ZnO, F:SnO₂, In:SnO₂, Ga:SnO₂, AZO, Ni, Pt, Au, Ag and Ir. Among them, the “:” in Cd:ZnO indicates doping.

In some embodiments, a material of the hole injection layer could be selected from one or more of poly (3,4-ethylenedioxythiophene)-polystyrene sulfonic acid (PEDOT:PSS), 2,3,5,6-tetrafluoro-7,7′,8,8′-tetracyanomethyl-p-benzoquinone (F4-TCNQ), copper phthalocyanine (CuPc), 1,4,5,8,9,11-hexaazabenzonitrile (HATCN), NiOₓ, MoOₓ, WOₓ, CrOₓ, CuO, MoSₓ, MoSeₓ, WSₓ, WSeₓ and CuS. A value range of x is 1-3.

In some embodiments, a material of the hole transport layer could be selected from one or more of poly (9,9-dioctyl fluorene-CO—N-(4-butylphenyl)diphenylamine) (TFB), polyvinyl carbazole (PVK), poly (N,N′ bis(4-butylphenyl)-N,N′-bis(phenyl)benzidine) (POLY-TPD), 4,4′,4″-tris(carbazole-9-yl)triphenylamine (TCTA), 4,4′-bis(9-carbazole) biphenyl (DCBP), N,N′-diphenyl-N,N′-bis(3-methylphenyl)-1,1′-biphenyl-4,4′-diamine (TPD) and N,N′-diphenyl-N,N′-(1-naphthyl)-1,1′-biphenyl-4,4′-diamine (NPB).

In some embodiments, if the light emitting diode is a quantum dot light emitting diode, a material of the light emitting layer 20 could include, but is not limited to, a single-component quantum dot, a core-shell structure quantum dot, an inorganic perovskite quantum dot or an organic-inorganic hybrid perovskite quantum dot. An average particle size of the quantum dot could be 5-10 nm, such as 5 nm, 6 nm, 7 nm, 8 nm, 9 nm or 10 nm.

The quantum dot is a single-component quantum dot or a core-shell structure quantum dot, a material of the single-component quantum dot, a core material of the core-shell structure quantum dot and a shell material of the core-shell structure quantum dot could be respectively selected from but not limited to one or more of II-VI compound, III-V compound, IV-VI compound, and I-III-VI compound. The II-VI compound is selected from one or more of CdS, CdSc, CdTe, ZnS, ZnSe, ZnTc, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSc, CdZnTe, CdHgS, CdHgSe, CdHgTe, HgZnS, HgZnSc, HgZnTe, CdZnSeS, CdZnSeTe, CdZnSTe, CdHgSeS, CdHgSeTe, CdHgSTe, HgZnSeS, HgZnSeTe and HgZnSTe. The III-V compound is selected from one or more of GaN, GaP, GaAs, GaSb, AlN, AIP, AlAs, AlSb, InN, InP, InAs, InSb, GaNP, GaNAs, GaNSb, GaPAs, GaPSb, AlNP, AlNAs, AlNSb, AIPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs and InAlPSb. The IV-VI compound is selected from one or more of SnS, SnSe, SnTe, PbS, PbSc, PbTe, SnSeS, SnSeTe, SnSTe, PbSeS, PbSeTe, PbSTe, SnPbS, SnPbSc, SnPbTe, SnPbSSe, SnPbSeTe and SnPbSTe. The I-III-VI compound is selected from one or more of CuInS₂, CuInSc₂ and AgInS₂. It should be noted that for the materials of the single-component quantum dot, or the core material of the core-shell structure quantum dot or the shell material of the core-shell structure quantum dot, a chemical formula provided only shows the element composition, but does not show the content of each element. For example, CdZnSe only means that it is composed of three elements: Cd, Zn and Se. If it means the content of each element, it should be CdₓZn₁₋ₓSc, with 0<x<1.

For the inorganic perovskite quantum dot, a general structural formula of the inorganic perovskite quantum dot is AMX₃, where A is Cs⁺, M is divalent metal cation selected from Pb²⁺, Sn²⁺, Cu²⁺, Ni²⁺, Cd²⁺, Cr²⁺, Mn²⁺, Co²⁺, Fe²⁺, Ge²⁺, Yb²⁺ or Eu²⁺, and X is halogen anion selected from Cl⁻, Br⁻ or I⁻.

For the organic perovskite quantum dot, a general structural formula of the organic perovskite quantum dot is CMX₃, where C is formamidinyl, M is divalent metal cation selected from Pb²⁺, Sn²⁺, Cu²⁺, Ni²⁺, Cd²⁺, Cr²⁺, Mn²⁺, Co²⁺, Fe²⁺, Ge²⁺, Yb²⁺ or Eu²⁺, and X is halogen anion selected from Cl⁻, Br⁻ or I⁻.

For the organic-inorganic hybrid quantum dot, a general structural formula of the organic-inorganic hybrid quantum dot is BMX₃, where B is organic amine cations selected from CH₃(CH₂)ₙ₋₂NH³⁺ (n≥2) or NH₃(CH₂)ₙNH₃²⁺ (n≥2), Mis divalent metal cation selected from Pb²⁺, Sn²⁺, Cu²⁺, Ni²⁺, Cd²⁺, Cr²⁺, Mn²⁺, Co²⁺, Fe²⁺, Ge²⁺, Yb²⁺ or Eu²⁺, and X is halogen anion selected from Cl⁻, Br⁻ or I⁻.

It could be understood that the material of the light emitting layer 20 includes quantum dot, the material of the light emitting layer 20 also includes ligand attached to a surface of the quantum dot. The ligand includes, but are not limited to, one or more of amine ligand, carboxylic acid ligand, thiol ligand, (oxygen) phosphine ligand, phospholipid, soft phospholipids or polyvinyl pyridine. The amine ligand is selected from one or more of oleylamine, n-butylamine, n-octylamine, octamine, 1,2-ethylenediamine or octamine. The carboxylic acid ligand is selected from one or more of oleic acid, acetic acid, butyric acid, valeric acid, caproic acid, arachidic acid, decadecanoic acid, undecylenic acid, tetradecanoic acid or stearic acid. The thiol ligand is selected from one or more of ethyl mercaptan, propyl mercaptan, mercaptoethanol, phenylmercaptan, octyl mercaptan, octadecyl mercaptan, dodecyl mercaptan or octadecyl mercaptan. The phosphine ligand is selected from one or more of trioctylphosphine or trioctylphosphine oxide.

In some embodiments, the light emitting diode is an organic light emitting diode, a material of the light emitting layer 20 could be an organic light emitting material.

Further, the material of the light emitting layer 20 could be a red light-emitting material, a green light-emitting material, or a blue light-emitting material, which is not limited.

In some embodiments, the metal oxide could be selected from one or more of ZnO, SnO₂, ITO, Fe₂O₃, CrO₃, TiO₂, WO₃, CdO, CuO and MoO₂.

In some embodiments, a material of the cathode 40 could be selected from one or more of metallic materials, carbon materials and metal oxides. Further, the metallic materials could include but not limited to Al, Ag, Cu, Mo, Au, Ba, Ca and Mg. The carbon materials could include but not limited to graphite, carbon nanotube, graphene, and carbon fiber. The metal oxides could be doped or undoped metal oxide, including but not limited to ITO, FTO, ATO, AZO, GZO, IZO, MZO and AMO. Further, when the material of the cathode 40 is selected from a plurality of the metal materials, the carbon materials and the metal oxides, the cathode 40 could be a composite electrode with metal sandwiched between doped or undoped transparent metal oxides. Specifically, the composite electrode could include but not limited to AZO/Ag/AZO, AZO/AI/AZO, ITO/Ag/ITO, ITO/AI/ITO, ZnO/Ag/ZnO, ZnO/Al/ZnO, TiO₂/Ag/TiO₂, TiO₂/Al/TiO₂, ZnS/Ag/ZnS, ZnS/Al/ZnS, TiO₂/Ag/TiO₂, TiO₂/Al/TiO₂. The above expression of AZO/Ag/AZO indicates that there is Ag between AZOs.

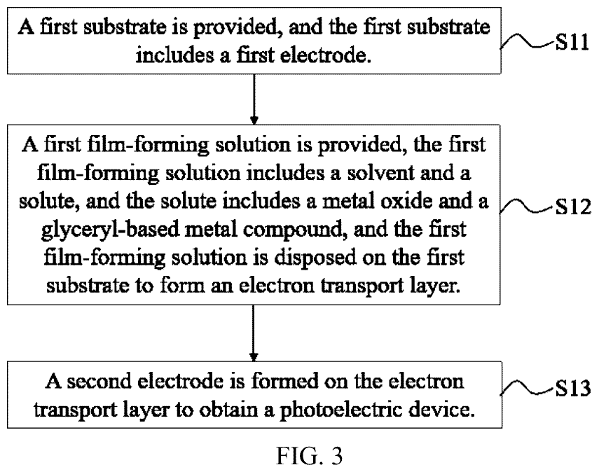

In the third aspect, referring to FIG. 3, the present disclosure proposes a preparation method of a photoelectric device which includes step S11-S13.

In step S11, a first substrate is provided, and the first substrate includes a first electrode.

In step S12, a first film-forming solution is provided, the first film-forming solution includes a solvent and a solute, and the solute includes a metal oxide and a glyceryl-based metal compound, and the first film-forming solution is disposed on the first substrate to form an electron transport layer 30.

In step S13, a second electrode is formed on the electron transport layer 30 to obtain a photoelectric device.

In some embodiments, the photovoltaic device is an upright photovoltaic device. The first substrate includes an anode 10 and a light emitting layer 20 which are stacked. The first film-forming solution is disposed on the side of the light emitting layer 20 far from the anode 10 to form the electron transport layer 30. A cathode 40 is formed on the electron transport layer 30 to obtain the photoelectric device.

In some embodiments, the first substrate further includes a hole functional layer 50, disposed between the anode 10 and the light emitting layer 20.

It should be noted that the photoelectric device prepared by this method is an upright photovoltaic device. Further, other functional layers such as a hole blocking layer, a hole transport layer, a hole injection layer and the like may be included between the anode 10 and the light emitting layer 20. Other film layers, such as an electron blocking layer, could also be provided between the light emitting layer 20 and the electron transport layer 30, which is not limited. It could be understood that in the preparation of an upright photovoltaic device, after the electron transport layer 30 is formed, an electron injection layer, a cathode 40, an encapsulation layer and other film layers could be further formed on the electron transport layer 30 to form a complete photovoltaic device.

In other embodiments, the photovoltaic device is an inverted photovoltaic device. The first substrate includes a cathode 40. The first film-forming solution is disposed on the cathode 40 to form the electron transport layer 30. A light emitting layer 20 and an anode 10 are sequentially formed on the electron transport layer 30 to obtain the photoelectric device.

In some embodiments, after the light emitting layer 20 is formed on the electron transport layer 30, the hole functional layer 50 and the anode 10 are further formed to obtain the photoelectric device.

It should be noted that the photoelectric device prepared by this method is an inverted photovoltaic device. The word “on” in the film-forming solution deposited on the cathode is in a broad sense. For example, in some embodiments, the cathode is also provided with an electron injection layer. At this time, the film-forming solution is directly deposited on the electron injection layer, but it could still be regarded as the film-forming solution deposited on the cathode. It could be understood that in the preparation of an inverted photovoltaic device, after the electron transport layer 303 is formed, a light emitting layer 20, a hole blocking layer, a hole transport layer, a hole injection layer, an anode 10 and other film layers could be further formed on the electron transport layer 30 to form a complete photoelectric device.

In some embodiments, the anode 10, the light emitting layer 20 and the cathode 40 could be formed by evaporation, inkjet printing, spin coating and other methods, which are not limited.

In some embodiments, a metal element in the glycerol-based metal compound could be selected from one or more of Zn, Sn, In, Fe, Cr, Ti, W, Cd, Cu and Mo.

In some embodiments, the glycerol-based metal compound is zinc glyceryl.

In some embodiments, the metal oxide could be selected from one or more of ZnO, SnO₂, ITO, Fe₂O₃, CrO₃, TiO₂, WO₃, CdO, CuO and MoO₂.

In some embodiments, a molar ratio between the glycerol-based metal compound and the metal oxide is (1-9):100, such as 2:100, 3:100, 4:100, 5:100, 6:100, 7:100, 8:100, etc.

In some embodiments, a solvent in the first film-forming solution could be selected from one or more of ethanol, propanol, 2propanol, n-butanol, 2butanol, tert-butanol, n-amyl alcohol, n,n-dimethylformamide and dimethyl sulfoxide.

A solvent in the second film-forming solution could be selected from one or more of ethanol, propanol, 2propanol, n-butanol, 2butanol, tert-butanol, n-amyl alcohol, n,n-dimethylformamide and dimethyl sulfoxide.

It could be understood that the solvent of the first film-forming solution and the second film-forming solution could be selected in the same range, but they could be selected from different solvents.

### Example 1

This example provides a composite material. The composite material includes zinc glycerol and zinc oxide, wherein a molar ratio of zinc glycerol and zinc oxide is 1:100.

### Example 2

This example provides a composite material. The composite material includes zinc glycerol and zinc oxide, wherein a molar ratio of zinc glycerol and zinc oxide is 3:100.

### Example 3

This example provides a composite material. The composite material includes zinc glycerol and zinc oxide, wherein a molar ratio of zinc glycerol and zinc oxide is 5:100.

### Example 4

This example provides a composite material. The composite material includes zinc glycerol and zinc oxide, wherein a molar ratio of zinc glycerol and zinc oxide is 7:100.

### Example 5

This example provides a composite material. The composite material includes zinc glycerol and zinc oxide, wherein a molar ratio of zinc glycerol and zinc oxide is 9:100.

### Example 6

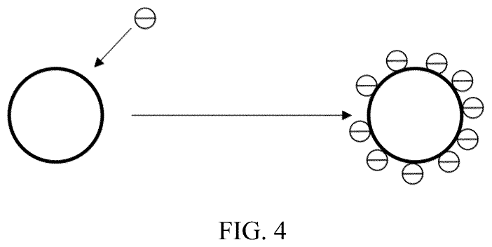

This example provides a composite material. The composite material includes zinc glycerol and zinc oxide, wherein a molar ratio of zinc glycerol and zinc oxide is 3:100. A surface of the zinc oxide is bonded with nitro group, and a schematic diagram of the nitro group on the surface of the zinc oxide is shown in FIG. 4.

### Example 7

This example provides a composite material. The composite material includes zinc glycerol and zinc oxide, wherein a molar ratio of zinc glycerol and zinc oxide is 3:100. A surface of the zinc oxide is bonded with vinyl group.

### Example 8

This example provides a composite material. The composite material includes zinc glycerol and zinc oxide, wherein a molar ratio of zinc glycerol and zinc oxide is 3:100. A surface of the zinc oxide is bonded with F atom group.

### Example 9

This example provides a composite material. The composite material includes zinc glycerol and zinc oxide, wherein a molar ratio of zinc glycerol and zinc oxide is 3:100. A surface of the zinc oxide is bonded with Cl atom group.

### Example 10

This example provides a composite material. The composite material includes zinc glycerol and zinc oxide, wherein a molar ratio of zinc glycerol and zinc oxide is 3:100. A surface of the zinc oxide is bonded with Br atom group.

### Example 11

This example provides a composite material. The composite material includes zinc glycerol and zinc oxide, wherein a molar ratio of zinc glycerol and zinc oxide is 3:100. A surface of the zinc oxide is bonded with nitro group and Br atom group.

### Example 12

This example provides a composite material. The composite material includes zinc glycerol and zinc oxide, wherein a molar ratio of zinc glycerol and zinc oxide is 3:100. A surface of the zinc oxide is bonded with vinyl group and Br atom group.

### Example 13

This example provides a composite material. The composite material includes zinc glycerol and zinc oxide, wherein a molar ratio of zinc glycerol and zinc oxide is 3:100. A surface of the zinc oxide is bonded with vinyl group and nitro group.

### Example 14

This example provides a composite material. The composite material includes zinc glycerol and zinc oxide, wherein a molar ratio of zinc glycerol and zinc oxide is 3:100. A surface of the zinc oxide is bonded with vinyl group, nitro group and Br atom group.

### Example 15

This example provides a composite material. The composite material includes zinc glycerol, ZnO and SnO₂, wherein a molar ratio of zinc glycerol, ZnO and SnO₂ is 3:50:50.

### Example 16

This example provides a composite material. The composite material includes zinc glycerol and WO₃, wherein a molar ratio of zinc glycerol and WO₃ is 3:80. Surfaces of WO₃ and zinc glycerol are bonded with nitro groups.

### Example 17

This example provides a composite material. The composite material includes tin glycerol and SnO₂, wherein a molar ratio of tin glycerol and SnO₂ is 3:80.

### Example 18

This example provides a photoelectric device, which includes an anode, a hole injection layer, a hole transport layer, a quantum dot light emitting layer, an electron transport layer and a cathode which are sequentially stacked. Wherein a material of the electron transport layer is the composite material O provided in Example 1.

This example also provides a preparation method of the photoelectric device includes steps S1-S6.

In step S1, a substrate is provided, and an anode is formed on the substrate by vacuum evaporation of Ag/ITO/Ag composite electrode.

In step S2, MCC is spin-coated on the anode to prepare a hole injection layer.

In step S3, TFB is spin-coated on the hole injection layer to prepare a hole transport layer.

In step S4, a quantum dot ZnSe/CdZnSe/CdZnS is spin-coated on the hole transport layer to prepare a quantum dot light emitting layer.

In step S5, a film-forming solution for preparing an electron transport layer is spin-coated on the quantum dot light emitting layer to prepare the electron transport layer, and wherein a solute of the film-forming solution is the composite material provided in Example 1.

In step S6, Ag is evaporated on the electron transport layer to form a cathode.

### Example 19

This example provides a photoelectric device, which includes an anode, a hole injection layer, a hole transport layer, a quantum dot light emitting layer, an electron transport layer and a cathode which are sequentially stacked. Wherein a material of the electron transport layer is the composite material provided in Example 2.

This example also provides a preparation method of the photoelectric device. In the preparation method of this example, the solute of the film-forming solution in step S5 of Example 18 was replaced by the composite material provided in Example 2, and the other steps were the same as those provided in Example 18.

### Example 20

This example provides a photoelectric device, which includes an anode, a hole injection layer, a hole transport layer, a quantum dot light emitting layer, an electron transport layer and a cathode which are sequentially stacked. Wherein a material of the electron transport layer is the composite material provided in Example 3.

This example also provides a preparation method of the photoelectric device. In the preparation method of this example, the solute of the film-forming solution in step S5 of Example 18 was replaced by the composite material provided in Example 3, and the other steps were the same as those provided in Example 18.

### Example 21

This example provides a photoelectric device, which includes an anode, a hole injection layer, a hole transport layer, a quantum dot light emitting layer, an electron transport layer and a cathode which are sequentially stacked. Wherein a material of the electron transport layer is the composite material provided in Example 4.

This example also provides a preparation method of the photoelectric device. In the preparation method of this example, the solute of the film-forming solution in step S5 of Example 18 was replaced by the composite material provided in Example 4, and the other steps were the same as those provided in Example 18.

### Example 22

This example provides a photoelectric device, which includes an anode, a hole injection layer, a hole transport layer, a quantum dot light emitting layer, an electron transport layer and a cathode which are sequentially stacked. Wherein a material of the electron transport layer is the composite material provided in Example 5.

This example also provides a preparation method of the photoelectric device. In the preparation method of this example, the solute of the film-forming solution in step S5 of Example 18 was replaced by the composite material provided in Example 5, and the other steps were the same as those provided in Example 18.

### Example 23

This example provides a photoelectric device, which includes an anode, a hole injection layer, a hole transport layer, a quantum dot light emitting layer, an electron transport layer and a cathode which are sequentially stacked. Wherein a material of the electron transport layer is the composite material provided in Example 6.

This example also provides a preparation method of the photoelectric device includes steps S1-S6.

In steps S1-S4, the same as steps S1-S4 in the preparation method provided in Example 18.

In step S5, a film-forming solution for preparing an electron transport layer is spin-coated on the quantum dot light emitting layer to prepare the electron transport layer, and wherein a solute of the film-forming solution is the composite material provided in Example 6. The ZnO in the composite material undergoes ligand exchange, which includes: 30 mg/mL ethanol solution of ZnO is mixed with sodium amino, and then hydrogen peroxide is added to obtain a mixed solution, which is used to introduce nitro group on the surface of ZnO, wherein a molar ratio of the sodium amino to ZnO is 3:100.

In step S6, Ag is evaporated on the electron transport layer to form a cathode.

### Example 24

This example provides a photoelectric device, which includes an anode, a hole injection layer, a hole transport layer, a quantum dot light emitting layer, an electron transport layer and a cathode which are sequentially stacked. Wherein a material of the electron transport layer is the composite material provided in Example 7.

This example also provides a preparation method of the photoelectric device includes steps S1-S6.

In steps S1-S4, the same as steps S1-S4 in the preparation method provided in Example 18.

In step S5, a film-forming solution for preparing an electron transport layer is spin-coated on the quantum dot light emitting layer to prepare the electron transport layer, and wherein a solute of the film-forming solution is the composite material provided in Example 7. The ZnO in the composite material undergoes ligand exchange, which includes: 30 mg/mL ethanol solution of ZnO is mixed with vinyl chloride to obtain a mixed solution, which is used to introduce vinyl group on the surface of ZnO, wherein a molar ratio of the vinyl chloride to ZnO is 3:100.

In step S6, Ag is evaporated on the electron transport layer to form a cathode.

### Example 25

This example provides a photoelectric device, which includes an anode, a hole injection layer, a hole transport layer, a quantum dot light emitting layer, an electron transport layer and a cathode which are sequentially stacked. Wherein a material of the electron transport layer is the composite material provided in Example 8.

This example also provides a preparation method of the photoelectric device includes steps S1-S6.

In steps S1-S4, the same as steps S1-S4 in the preparation method provided in Example 18.

In step S5, a film-forming solution for preparing an electron transport layer is spin-coated on the quantum dot light emitting layer to prepare the electron transport layer, and wherein a solute of the film-forming solution is the composite material provided in Example 8. The ZnO in the composite material undergoes ligand exchange, which includes: 30 mg/mL ethanol solution of ZnO is mixed with NaF to obtain a mixed solution, which is used to introduce F atom group on the surface of ZnO, wherein a molar ratio of the NaF to ZnO is 3:100.

In step S6, Ag is evaporated on the electron transport layer to form a cathode.

### Example 26

This example provides a photoelectric device, which includes an anode, a hole injection layer, a hole transport layer, a quantum dot light emitting layer, an electron transport layer and a cathode which are sequentially stacked. Wherein a material of the electron transport layer is the composite material provided in Example 9.

This example also provides a preparation method of the photoelectric device includes steps S1-S6.

In steps S1-S4, the same as steps S1-S4 in the preparation method provided in Example 18.

In step S5, a film-forming solution for preparing an electron transport layer is spin-coated on the quantum dot light emitting layer to prepare the electron transport layer, and wherein a solute of the film-forming solution is the composite material provided in Example 9. The ZnO in the composite material undergoes ligand exchange, which includes: 30 mg/mL ethanol solution of ZnO is mixed with NaCl to obtain a mixed solution, which is used to introduce Cl atom group on the surface of ZnO, wherein a molar ratio of the NaCl to ZnO is 3:100.

In step S6, Ag is evaporated on the electron transport layer to form a cathode.

### Example 27

This example provides a photoelectric device, which includes an anode, a hole injection layer, a hole transport layer, a quantum dot light emitting layer, an electron transport layer and a cathode which are sequentially stacked. Wherein a material of the electron transport layer is the composite material provided in Example 10.

This example also provides a preparation method of the photoelectric device includes steps S1-S6.

In steps S1-S4, the same as steps S1-S4 in the preparation method provided in Example 18.

In step S5, a film-forming solution for preparing an electron transport layer is spin-coated on the quantum dot light emitting layer to prepare the electron transport layer, and wherein a solute of the film-forming solution is the composite material provided in Example 10. The ZnO in the composite material undergoes ligand exchange, which includes: 30 mg/mL ethanol solution of ZnO is mixed with NaBr to obtain a mixed solution, which is used to introduce Br atom group on the surface of ZnO, wherein a molar ratio of the NaBr to ZnO is 3:100.

In step S6, Ag is evaporated on the electron transport layer to form a cathode.

### Example 28

This example provides a photoelectric device, which includes an anode, a hole injection layer, a hole transport layer, a quantum dot light emitting layer, an electron transport layer and a cathode which are sequentially stacked. Wherein a material of the electron transport layer is the composite material provided in Example 11.

This example also provides a preparation method of the photoelectric device includes steps S1-S6.

In steps S1-S4, the same as steps S1-S4 in the preparation method provided in Example 18.

In step S5, a film-forming solution for preparing an electron transport layer is spin-coated on the quantum dot light emitting layer to prepare the electron transport layer, and wherein a solute of the film-forming solution is the composite material provided in Example 11. The ZnO in the composite material undergoes ligand exchange, which includes: 30 mg/mL ethanol solution of ZnO is mixed with NaBr and sodium amino, and then hydrogen peroxide is added to obtain a mixed solution, which is used to introduce Br atom group and nitro group on the surface of ZnO, wherein a molar ratio of the NaBr to ZnO is 3:100, and a molar ratio of the sodium amino to ZnO is 3:100.

In step S6, Ag is evaporated on the electron transport layer to form a cathode.

### Example 29

This example provides a photoelectric device, which includes an anode, a hole injection layer, a hole transport layer, a quantum dot light emitting layer, an electron transport layer and a cathode which are sequentially stacked. Wherein a material of the electron transport layer is the composite material provided in Example 12.

This example also provides a preparation method of the photoelectric device includes steps S1-S6.

In steps S1-S4, the same as steps S1-S4 in the preparation method provided in Example 18.

In step S5, a film-forming solution for preparing an electron transport layer is spin-coated on the quantum dot light emitting layer to prepare the electron transport layer, and wherein a solute of the film-forming solution is the composite material provided in Example 12. The ZnO in the composite material undergoes ligand exchange, which includes: 30 mg/mL ethanol solution of ZnO is mixed with NaBr and vinyl chloride to obtain a mixed solution, which is used to introduce Br atom group and vinyl group on the surface of ZnO, wherein a molar ratio of the NaBr to ZnO is 3:100, and a molar ratio of the vinyl chloride to ZnO is 3:100.

In step S6, Ag is evaporated on the electron transport layer to form a cathode.

### Example 30

This example provides a photoelectric device, which includes an anode, a hole injection layer, a hole transport layer, a quantum dot light emitting layer, an electron transport layer and a cathode which are sequentially stacked. Wherein a material of the electron transport layer is the composite material provided in Example 13.

This example also provides a preparation method of the photoelectric device includes steps S1-S6.

In steps S1-S4, the same as steps S1-S4 in the preparation method provided in Example 18.

In step S5, a film-forming solution for preparing an electron transport layer is spin-coated on the quantum dot light emitting layer to prepare the electron transport layer, and wherein a solute of the film-forming solution is the composite material provided in Example 13. The ZnO in the composite material undergoes ligand exchange, which includes: 30 mg/mL ethanol solution of ZnO is mixed with sodium amino and vinyl chloride, and then hydrogen peroxide is added to obtain a mixed solution, which is used to introduce nitro group and vinyl group on the surface of ZnO, wherein a molar ratio of the sodium amino to ZnO is 3:100, and a molar ratio of the vinyl chloride to ZnO is 3:100.

In step S6, Ag is evaporated on the electron transport layer to form a cathode.

### Example 31

This example provides a photoelectric device, which includes an anode, a hole injection layer, a hole transport layer, a quantum dot light emitting layer, an electron transport layer and a cathode which are sequentially stacked. Wherein a material of the electron transport layer is the composite material provided in Example 14.

This example also provides a preparation method of the photoelectric device includes steps S1-S6.

In steps S1-S4, the same as steps S1-S4 in the preparation method provided in Example 18.

In step S5, a film-forming solution for preparing an electron transport layer is spin-coated on the quantum dot light emitting layer to prepare the electron transport layer, and wherein a solute of the film-forming solution is the composite material provided in Example 14. The ZnO in the composite material undergoes ligand exchange, which includes: 30 mg/mL ethanol solution of ZnO is mixed with NaBr, sodium amino and vinyl chloride, and then hydrogen peroxide is added to obtain a mixed solution, which is used to introduce Br atom group, nitro group and vinyl group on the surface of ZnO, wherein a molar ratio of the NaBr to ZnO is 3:100, a molar ratio of the sodium amino to ZnO is 3:100, and a molar ratio of the vinyl chloride to ZnO is 3:100

In step S6, Ag is evaporated on the electron transport layer to form a cathode.

### Example 32

This example provides a photoelectric device, which includes an anode, a hole injection layer, a hole transport layer, a quantum dot light emitting layer, an electron transport layer and a cathode which are sequentially stacked. Wherein a material of the electron transport layer is the composite material provided in Example 15.

This example also provides a preparation method of the photoelectric device includes steps S1-S6.

In steps S1-S4, the same as steps S1-S4 in the preparation method provided in Example 18.

In step S5, a film-forming solution for preparing an electron transport layer is spin-coated on the quantum dot light emitting layer to prepare the electron transport layer, and wherein a solute of the film-forming solution is the composite material provided in Example 15.

In step S6, Ag is evaporated on the electron transport layer to form a cathode.

### Example 33

This example provides a photoelectric device, which includes an anode, a hole injection layer, a hole transport layer, a quantum dot light emitting layer, an electron transport layer and a cathode which are sequentially stacked. Wherein a material of the electron transport layer is the composite material provided in Example 1.

This example also provides a preparation method of the photoelectric device includes steps S1-S5.

In step S1, a substrate is provided, and an anode is formed on the substrate by vacuum evaporation of ITO composite electrode.

In step S2, TFB is inkjet printed on the anode to prepare hole transport layer.

In step S3, a quantum dot ZnSe/CdZnSe/CdZnS is inkjet printed on the hole transport layer to prepare a quantum dot light emitting layer.

In step S4, a film-forming solution for preparing an electron transport layer is inkjet printed on the quantum dot light emitting layer to prepare the electron transport layer, and the preparation of the film-forming solution includes:
zinc acetate dihydrate and ethanol are mixed and stirred to obtain 0.04 g/mL zinc acetate dihydrate ethanol solution;
the zinc acetate dihydrate ethanol solution is mixed with ethanolamine, and a volume ratio of the ethanolamine to the zinc acetate dihydrate ethanol solution is 1:150;
the zinc acetate dihydrate ethanol solution added with the ethanolamine is stirred at 60° C. for 10 min to obtain ZnO solution;
the ZnO solution is prepared into 30 mg/mL ZnO ethanol solution after standing for more than 24 hours;
the 30 mg/mL ZnO ethanol solution and zinc glycerol are mixed, in which a molar ratio of the zinc glycerol to ZnO is 3:100.

In step S5, Ag is evaporated on the electron transport layer to form a cathode.

### Example 34

This example provides a photoelectric device, which includes an anode, a hole injection layer, a hole transport layer, a quantum dot light emitting layer, an electron transport layer and a cathode which are sequentially stacked. Wherein a material of the electron transport layer is the composite material provided in Example 16.

This example also provides a preparation method of the photoelectric device includes steps S1-S6.

In step S1, a substrate is provided, and an anode is formed on the substrate by vacuum evaporation of an Ag electrode.

In step S2, PEDOT:PSS is inkjet printed on the anode to prepare a hole injection layer.

In step S3, PVK is inkjet printed on the hole injection layer to prepare a hole transport layer.

In step S4, Alq₃ is evaporated on the hole transport layer to prepare an organic light emitting layer.

In step S5, a film-forming solution for preparing an electron transport layer is spin-coated on the organic light emitting layer to prepare the electron transport layer, and wherein a solute of the film-forming solution is the composite material provided in Example 16.

In step S6, Ag is evaporated on the electron transport layer to form a cathode.

### Example 35

This example provides a photoelectric device, which includes an anode, a hole injection layer, a hole transport layer, a quantum dot light emitting layer, an electron transport layer and a cathode which are sequentially stacked. Wherein a material of the electron transport layer is the composite material provided in Example 17.

This example also provides a preparation method of the photoelectric device includes steps S1-S5

In step S1, a substrate is provided, and a cathode is formed on the substrate by vacuum evaporation of an Ag electrode.

In step S2, a film-forming solution for preparing an electron transport layer is spin-coated on the cathode to prepare the electron transport layer, and wherein a solute of the film-forming solution is the composite material provided in Example 17.

In step S3, Alq₃ is evaporated on the electron transport layer to prepare an organic light emitting layer.

In step S4, PVK is spin-coated on the organic light emitting layer to prepare a hole transport layer.

In step S5, ITO is evaporated on the hole transport layer to form an anode.

### Comparative Example 1

This comparative example provides a photoelectric device, which includes an anode, a hole injection layer, a hole transport layer, a quantum dot light emitting layer, an electron transport layer and a cathode which are sequentially stacked. Wherein a material of the electron transport layer is ZnO.

This comparative example also provides a preparation method of the photoelectric device includes steps S1-S6

In step S1, a substrate is provided, and an anode is formed on the substrate by vacuum evaporation of Ag/ITO/Ag composite electrode.

In step S2, MCC is spin-coated on the anode to prepare a hole injection layer.

In step S3, TFB is spin-coated on the hole injection layer to prepare a hole transport layer.

In step S4, a quantum dot ZnSe/CdZnSe/CdZnS is spin-coated on the hole transport layer to prepare a quantum dot light emitting layer, “/” in ZnSe/CdZnSe/CdZnS represents the core-shell structure, that is, CdZnSe is used as middle layer to coat the core of ZnSe, and CdZnS is used as the outer layer to coat the middle layer of CdZnSe.

In step S5, ZnO is spin-coated on the quantum dot light emitting layer to prepare the electron transport layer.

In step S6, Ag is evaporated on the electron transport layer to form a cathode.

Under the temperature condition of 80° C., the lifetime and luminous efficiency of the light emitting diode devices of Examples 16-29 and Comparative Example 1 are tested at 1000 nit, and the results are shown in Table 1.

TABLE 1

| | CE@1000 nit | LT95@1000 nit |
|---|---|---|
| | (Cd/A) | (h) |
| Example 18 | 155.2 | 20445 |
| Example 19 | 190.6 | 38665 |
| Example 20 | 171 | 35889 |
| Example 21 | 151.3 | 22665 |
| Example 22 | 133 | 20235 |
| Example 23 | 229.9 | 49252 |
| Example 24 | 226.7 | 53001 |
| Example 25 | 233.5 | 53229 |
| Example 26 | 228.5 | 52077 |
| Example 27 | 230.8 | 54644 |
| Example 28 | 258.9 | 67625 |
| Example 29 | 260.5 | 68224 |
| Example 30 | 257.7 | 67885 |
| Example 31 | 267.8 | 77756 |
| Example 32 | 227.8 | 55326 |
| Example 33 | 245.3 | 63665 |
| Example 34 | 247.5 | 63887 |
| Example 35 | 238.5 | 56887 |
| Comparative Example 1 | 85.2 | 10556 |

In Table 1, CE@ 1000 nit indicates the efficiency of light emitting diodes at 80° C. and brightness of 1000 nit, in Cd/A.

LT95@ 1000 nit indicates the time taken by the light emitting diodes when its brightness decays to 95% of its original brightness at 80° C. and 1000 nit, in h.

From Table 1, it could be seen that the addition of glycerol-based metal compound could improve the luminous efficiency and lifetime of the device, and effectively alleviate the performance degradation of the device caused by the aging of the electron transport layer under high temperature test. At the same time, introducing hydrophobic group as surface ligand on the surface of electron transport material could further improve the luminous efficiency and lifetime of device, and the effect of introducing multiple hydrophobic groups is better than that of introducing a single hydrophobic group.

The light stability of the light emitting diodes of Examples 16-28 and Comparative Example 1 under illumination conditions is tested (25 devices are selected for each condition, and 4 points are tested for each device, that is, 100 data are tested for each condition). The test method is: under continuous illumination, test the quenching rate of the test point when the light emitting region of the device works for 2 hours, 24 hours and 48 hours. The lower the quenching rate of the test point in the light emitting region of the device, the better the light ability of the device, and the more difficult it is for the electron transport materials in the device to undergo photohydration reaction. The results are shown in Table 2.

TABLE 2

| | Quenching | Quenching | Quenching |
|---|---|---|---|
| | rate (%) | rate (%) | rate (%) |
| | (2 h) | (24 h) | (48 h) |
| Example 18 | 31 | 40 | 49 |
| Example 19 | 30 | 38 | 45 |
| Example 20 | 31 | 41 | 52 |
| Example 21 | 32 | 41 | 52 |
| Example 22 | 33 | 42 | 53 |
| Example 23 | 20 | 21 | 22 |
| Example 24 | 22 | 23 | 25 |
| Example 25 | 23 | 23 | 24 |
| Example 26 | 22 | 24 | 25 |
| Example 27 | 18 | 18 | 20 |
| Example 28 | 17 | 18 | 21 |
| Example 29 | 15 | 16 | 17 |
| Example 30 | 10 | 10 | 12 |
| Example 31 | 32 | 40 | 52 |
| Example 32 | 29 | 38 | 50 |
| Example 33 | 28 | 38 | 50 |
| Example 34 | 30 | 41 | 52 |
| Comparative Example 1 | 32 | 42 | 50 |

From Table 2, it could be seen that after introducing hydrophobic group, the quenching rate of the device test points has been greatly reduced. And with the increase of test time, the quenching rate of general light emitting diode increases, but the quenching rate of light emitting with hydrophobic group is almost unchanged. The introduction of hydrophobic group could effectively prevent the adverse effects of photohydration reaction on electron transport material, and then improve light stability.

Composite material, photoelectric device and preparation method therefor are described in detail above. The principles and embodiments of the present disclosure have been described with reference to specific embodiments, and the description of the above embodiments is merely intended to aid in the understanding of the method of the present disclosure and its core idea. At the same time, changes may be made by those skilled in the art to both the specific implementations and the scope of present disclosure in accordance with the teachings of the present disclosure. In view of the foregoing, the content of the present specification should not be construed as limiting the disclosure.

1. A composite material, comprising:
a metal oxide; and
a glycerol-based metal compound.

2. The composite material according to claim 1, wherein the composite material consists of the metal oxide and the glycerol-based metal compound.

3. The composite material according to claim 1, wherein a metal element in the glycerol-based metal compound is selected from one or more of Zn, Sn, In, Fe, Cr, Ti, W, Cd, Cu and Mo; and
the metal oxide is selected from one or more of ZnO, SnO₂, ITO, Fe₂O₃, CrO₃, TiO₂, WO₃, CdO, CuO and MoO₂.

4. The composite material according to claim 3, wherein the glycerol-based metal compound is zinc glyceryl.

5. The composite material according to claim 1, wherein a molar ratio between the glycerol-based metal compound and the metal oxide is (1-9):100; and
the metal oxide is metal oxide nanoparticle, and an average particle size of the metal oxide nanoparticle ranges between 3-5 nm.

6. The composite material according to claim 1, wherein a surface of one or more of the metal oxide and the glycerol-based metal compound is bonded with hydrophobic group.

7. The composite material according to claim 6, wherein the hydrophobic group is selected from one or more of vinyl group, nitro group and halogen atom group.

8. The composite material according to claim 6, wherein the surface of the metal oxide is bonded with a first hydrophobic group, and the surface of the glycerol-based metal compound is bonded with a second hydrophobic group; and the first hydrophobic group and the second hydrophobic group are independently selected from one or more of vinyl group, nitro group and halogen atom group.

9. A photoelectric device, comprising:
a cathode,
an anode; and
a functional layer, between the cathode and the anode, wherein the functional layer comprises an electron transport layer, and a material of the electron transport layer comprises the composite material according to claim 1.

10. The photoelectric device according to claim 9, wherein a material of the cathode is selected from one or more of metallic materials, carbon materials and metal oxides; the metallic materials are selected from one or more of Al, Ag, Cu, Mo, Au, Ba, Ca and Mg, the carbon materials are selected from one or more of graphite, carbon nanotube, graphene, and carbon fiber, and the metal oxides are selected from one or more of ITO, FTO, ATO, AZO, GZO, IZO, MZO and AMO; and
a material of the anode is selected from one or more of ITO, FTO, IZO, ITZO, ICO, SnO₂, In₂O₃, Cd:ZnO, F:SnO₂, In:SnO₂, Ga:SnO₂, AZO, Ni, Pt, Au, Ag and Ir.

11. The photoelectric device according to claim 9, wherein the functional layer further comprises a light emitting layer which disposed between the electron transport layer and the anode.

12. The photoelectric device according to claim 11, wherein a material of the light emitting layer is selected from one or more of single-component and/or core-shell structure II-VI compound, single-component and/or core-shell structure III-V compound, single-component and/or core-shell structure IV-VI compound, single-component and/or core-shell structure I-III-VI compound, inorganic perovskite quantum dot, organic perovskite quantum dots and organic-inorganic hybrid perovskite quantum dot;
the II-VI compound is selected from one or more of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe and HgZnSTe; the III-V compound is selected from one or more of GaN, GaP, GaAs, GaSb, AlN, AIP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs and InAlPSb; the IV-VI compound is selected from one or more of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe and SnPbSTe; and the I-III-VI compound is selected from one or more of CuInS₂, CuInSe₂ and AgInS₂;
a general structural formula of the inorganic perovskite quantum dot is AMX₃, where A is Cs⁺, M is divalent metal cation selected from Pb²⁺, Sn²⁺, Cu²⁺, Ni²⁺, Cd²⁺, Cr²⁺, Mn²⁺, Co²⁺, Fe²⁺, Ge²⁺, Yb²⁺ or Eu²⁺, and X is halogen anion selected from Cl⁻, Br⁻ or I⁻;
a general structural formula of the organic perovskite quantum dot is CMX₃, where C is formamidinyl, M is divalent metal cation selected from Pb²⁺, Sn²⁺, Cu²⁺, Ni²⁺, Cd²⁺, Cr²⁺, Mn²⁺, Co²⁺, Fe²⁺, Ge²⁺, Yb²⁺ or Eu²⁺, and X is halogen anion selected from Cl, Br or I;
a general structural formula of the organic-inorganic hybrid quantum dot is BMX₃, where B is organic amine cations selected from CH₃(CH₂)ₙ₋₂NH³⁺ (n≥2) or NH₃(CH₂)ₙNH₃²⁺ (n≥2), Mis divalent metal cation selected from Pb²⁺, Sn²⁺, Cu²⁺, Ni²⁺, Cd²⁺, Cr²⁺, Mn²⁺, Co²⁺, Fe²⁺, Ge²⁺, Yb²⁺ or Eu²⁺, and X is halogen anion selected from Cl⁻, Br⁻ or I⁻.

13. The photoelectric device according to claim 11, wherein the functional layer further comprises a hole functional layer which disposed between the light emitting layer and the anode, and the hole functional layer comprises one or more of a hole injection layer and a hole transport layer.

14. The photoelectric device according to claim 13, wherein a material of the hole injection layer is selected from one or more of poly (3,4-ethylenedioxythiophene)-polystyrene sulfonic acid, 2,3,5,6-tetrafluoro-7,7′,8,8′-tetracyanomethyl-p-benzoquinone, copper phthalocyanine, 1,4,5,8,9,11-hexaazabenzonitrile, microcrystalline cellulose, NiOₓ, MoOₓ, WOₓ, CrOₓ, CuO, MoSₓ, MoSeₓ, WSₓ, WSeₓ and CuS; and a value range of x is 1-3; and
a material of the hole transport layer is selected from one or more of poly (9,9-dioctyl fluorene-CO—N-(4-butylphenyl)diphenylamine), polyvinyl carbazole, poly (N,N′ bis(4-butylphenyl)-N,N′-bis(phenyl)benzidine), 4,4′,4″-tris(carbazole-9-yl)triphenylamine, 4,4′-bis(9-carbazole) biphenyl, N,N′-diphenyl-N,N′-bis(3-methylphenyl)-1,1′-biphenyl-4,4′-diamine and N,N′-diphenyl-N,N′-(1-naphthyl)-1, l′-biphenyl-4,4′-diamine.

15. A preparation method of a photoelectric device, comprising:
providing a first substrate, and the first substrate comprises a first electrode;
providing a first film-forming solution, the first film-forming solution comprises a solvent and a solute, and the solute comprises a metal oxide and a glyceryl-based metal compound, and disposing the first film-forming solution on the first substrate to form an electron transport layer; and
forming a second electrode on the electron transport layer to obtain a photoelectric device.

16. The preparation method according to claim 15, wherein the first substrate comprises an anode and a light emitting layer which are stacked; disposing the first film-forming solution on the side of the light emitting layer far from the anode to form the electron transport layer; forming a cathode on the electron transport layer to obtain the photoelectric device.

17. The preparation method according to claim 15, wherein the first substrate comprises a cathode; disposing the first film-forming solution on the cathode to form the electron transport layer; forming a light emitting layer and an anode on the electron transport layer to obtain the photoelectric device.

18. The preparation method according to claim 15, wherein a metal element in the glycerol-based metal compound is selected from one or more of Zn, Sn, In, Fe, Cr, Ti, W, Cd, Cu and Mo; and
the metal oxide is selected from one or more of ZnO, SnO₂, ITO, Fe₂O₃, CrO₃, TiO₂, WO₃, CdO, CuO and MoO₂.

19. The preparation method according to claim 18, wherein the glycerol-based metal compound is zinc glyceryl.

20. The preparation method according to claim 15, wherein a molar ratio between the glycerol-based metal compound and the metal oxide is (1-9):100; and
a solvent in the first film-forming solution is selected from one or more of ethanol, propanol, 2propanol, n-butanol, 2butanol, tert-butanol, n-amyl alcohol, n,n-dimethylformamide and dimethyl sulfoxide.
